(19) United States
(12) Patent Application Publication
(10) Pub. No.: US 2025/0119110 A1
(43) Pub. Date: Apr. 10, 2025

(54) MODULATOR INTEGRATED CIRCUIT PACKAGE

(71) Applicant: Cirrus Logic International Semiconductor Ltd., Edinburgh (GB)

(72) Inventors: John P. LESSO, Edinburgh (GB); Michael ROBINSON, Edinburgh (GB)

(73) Assignee: Cirrus Logic International Semiconductor Ltd., Edinburgh (GB)

(21) Appl. No.: 18/482,290

(22) Filed: Oct. 6, 2023

(51) Int. Cl. H03F 3/217

(52) U.S. Cl. CPC H03F 3/217; H03F 2200/03

(57) ABSTRACT

A modulator integrated circuit (IC) package comprising: signal modulator circuitry; and power modulator circuitry, wherein the signal modulator circuitry is configured to receive an input signal and to supply a modulated output signal to output stage circuitry external to the modulator IC package, and wherein the power modulator circuitry is configured to control power converter circuitry, external to the modulator IC package, operative to provide a supply voltage to the output stage circuitry.

### FIELD OF THE INVENTION

The present disclosure relates to a modulator integrated circuit package.

### BACKGROUND

Switching transducer drivers such as Class D amplifiers are increasingly being used in electronic devices for which power efficiency is important, such as mobile telephones, portable media players, laptop and tablet computers, wireless headphones, earphones and earbuds. Such transducer drivers are also increasingly finding use in automotive applications, e.g. in vehicle audio systems and the like.

A typical switching transducer driver (e.g. a Class D amplifier) includes a modulator stage and an output stage. In low-power applications such as portable audio devices it is common for both the modulator stage and the output stage to be integrated in a single integrated circuit. For higher power applications (e.g. applications where the output power is equal to or greater than 50 W), it may be desirable to implement the output stage separately from the modulator stage, e.g. using discrete off-chip devices.

### SUMMARY

According to a first aspect, the invention provides a modulator integrated circuit (IC) package comprising: signal modulator circuitry; and power modulator circuitry, wherein the signal modulator circuitry is configured to receive an input signal and to supply a modulated output signal to output stage circuitry external to the modulator IC package, and wherein the power modulator circuitry is configured to control power converter circuitry, external to the modulator IC package, operative to provide a supply voltage to the output stage circuitry.

The signal modulator circuitry and the power modulator circuitry may be integrated in a single integrated circuit die.

The signal modulator circuitry and the power modulator circuitry may be configured to receive a common clock signal.

The power modulator circuitry may be configured to control the power converter circuitry based on the supply voltage provided by the power converter circuitry to the output stage circuitry.

The modulator IC package may further comprise first monitor circuitry for monitoring the supply voltage provided by the power converter circuitry to the output stage circuitry.

The power modulator circuitry may be configured to control the power converter circuitry based at least in part on a first monitor output signal output by the first monitor circuitry.

The signal modulator circuitry may be configured to control a parameter of the modulated output signal based at least in part on a first monitor output signal output by the first monitor circuitry.

The parameter may comprise one or more of: a pulse width; a duty cycle; a peak signal amplitude; a gain applied to the modulated output signal; or a compression applied to the modulated output signal.

The first monitor circuitry may comprise analog to digital converter (ADC) circuitry.

An output of the first monitor circuitry may be coupled to an input of the signal modulator circuitry such that the signal monitor circuitry receives a first monitor output signal output by the first monitor circuitry.

The modulator IC package may further comprise second monitor circuitry for monitoring an operational parameter of the output stage circuitry.

The signal modulator circuitry may be configured to control a parameter of the modulated output signal based at least in part on a second monitor output signal output by the second monitor circuitry.

The parameter may comprise one or more of: a pulse width; a duty cycle; a peak signal amplitude; a gain applied to the modulated output signal; or a compression applied to the modulated output signal.

The signal modulator circuitry and the power modulator circuitry may be configured to communicate with each other.

The power modulator circuitry may be configured to receive a signal indicative of the input signal and to control the power converter circuitry based at least in part on the signal indicative of the input signal.

The power modulator circuitry may be operative to control the power converter circuitry to modulate the supply voltage based on the signal indicative of the input signal.

The power modulator circuitry may be operative to control the power converter circuitry to modulate the supply voltage between a plurality of different supply voltage levels based on the signal indicative of the input signal.

The power modulator circuitry may be operative to control the power converter circuitry to maintain a fixed voltage difference between the supply voltage and a voltage of the input signal or between the supply voltage and an output voltage of the output stage circuitry.

The modulator IC package may comprise a plurality of instances of signal modulator circuitry, wherein each instance of signal modulator circuitry is configured to receive an input signal and to supply a respective modulated output signal to a respective instance of output stage circuitry external to the modulator IC package.

The signal modulator circuitry may comprise class D modulator circuitry.

The signal modulator circuitry and/or the power modulator circuitry may be implemented in digital circuitry.

The modulated output signal may be for controlling output stage circuitry for driving one or more of: an audio transducer; a haptic transducer; a motor; and a lighting transducer.

According to a second aspect, the invention provides a module comprising: the modulator integrated circuit package of the first aspect; and switches of power converter circuitry; and/or switches of output stage circuitry, wherein the power modulator circuitry of the modulator integrated circuit package is operable to control the switches of the power converter circuitry; and/or wherein the signal modulator circuitry of the modulator integrated circuit package is operable to control the switches of the output stage circuitry.

The module may further comprise output filter circuitry for coupling to the output stage circuitry.

The output filter circuitry may comprise one or more of an inductor and a capacitor.

The modulator integrated circuit package may be implemented using devices based on a first semiconductor material or process. The switches of the power converter circuitry and/or the switches of the output stage circuitry may be implemented using devices based on a second semiconductor material or process that is different from the first semiconductor material or process.

For example, the modulator integrated circuit package may be implemented using silicon-based devices, and the switches of the power converter circuitry may be implemented using wide bandgap or high electron mobility devices.

According to a third aspect, the invention provides a host device comprising a modulator integrated circuit package according to the first aspect or a module according to the second aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device; a vehicle audio system; a lighting system; a haptic system; a motor control system; or a vehicle.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of a modulator integrated circuit package according to the present disclosure;

FIG. 2 is a schematic representation of a further modulator integrated circuit package according to the present disclosure;

FIG. 3 is a schematic representation of a further modulator integrated circuit package according to the present disclosure;

FIG. 4 is a schematic representation of example single-ended output stage circuitry;

FIG. 5 is a schematic representation of example full bridge differential output stage circuitry;

FIG. 6 is a schematic representation of example multi-level single-ended output stage circuitry;

FIG. 7 is a schematic representation of example DC-DC converter circuitry;

FIG. 8 is a schematic representation of further example DC-DC converter circuitry;

FIG. 9 is a schematic representation of a module comprising a modulator integrated circuit package and switches of output stage circuitry according the present disclosure;

FIG. 10 is a schematic representation of a module comprising a modulator integrated circuit package and switches of power converter circuitry according the present disclosure; and

FIG. 11 is a schematic representation of a module comprising a modulator integrated circuit package, switches of output stage circuitry, and switches of power converter circuitry according the present disclosure.

### DETAILED DESCRIPTION

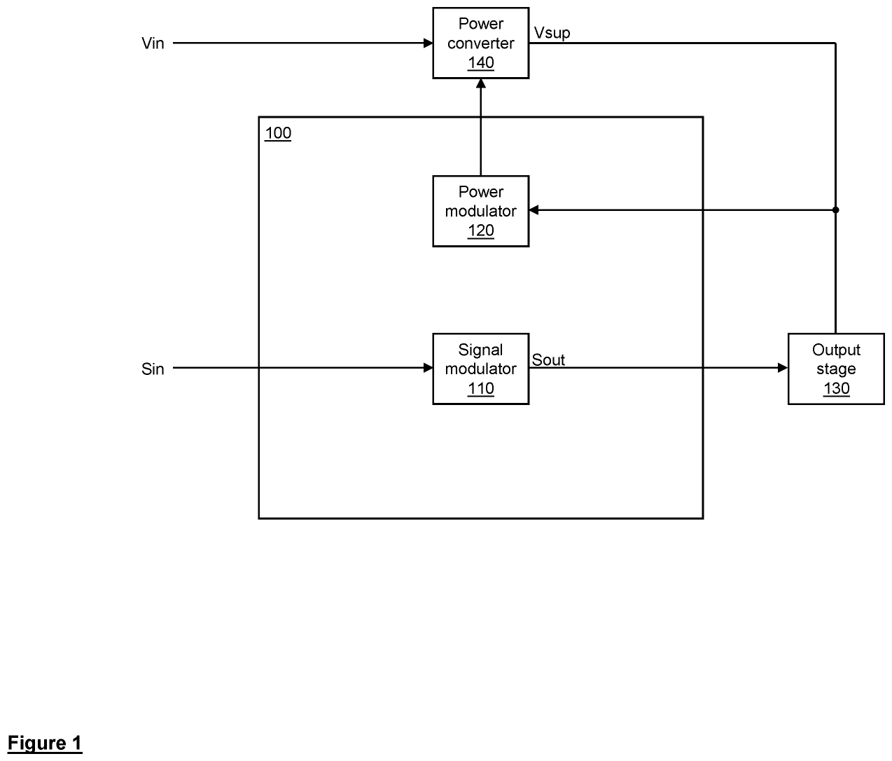

FIG. 1 is a schematic representation of an example modulator integrated circuit (IC) package. The modulator IC package, shown generally at 100 in FIG. 1, comprises signal modulator circuitry 110 and power modulator circuitry 120. In some examples the modulator IC package 100 is implemented in a single IC die, such that the signal modulator circuitry 110 and the power modulator circuitry 120 are integrated in a single IC die. In other examples, the signal modulator circuitry 110 may be implemented on a first IC die and the power modulator circuitry 120 may be implemented on a second IC die, with the first and second IC die being provided within the modulator IC package 100.

The signal modulator circuitry 110 is configured to receive an input signal Sin and to generate a modulated output signal Sout for driving output stage circuitry 130 which is provided externally of the modulator IC package 100. The signal modulator circuitry 110 may be, for example, Class D modulator circuitry and may be configured to generate a pulse width modulated (PWM) output signal Sout. The signal modulator circuitry 110 may be implemented in digital circuitry or in analog circuitry, or in a mixture of digital and analog circuitry.

The output stage circuitry 130 is configured to generate one or more driving signals for driving one or more output transducers, based on the modulated output signal Sout received from the signal modulator circuitry 110. The output stage circuitry 130 may comprise, for example, single-ended output stage circuitry, multi-level single-ended output stage circuitry, or bridge-tied load output stage circuitry. The output transducer(s) may be, for example, one or more audio transducers (e.g. speakers, earphones, earbuds or the like), one or more haptic transducers (e.g. linear resonant actuators or the like), one or more motors or one or more lighting transducer such as light emitting diodes (LEDs).

Power converter circuitry 140 external to the modulator IC package 100 is configured to receive an input voltage Vin (e.g. from a battery of a host device that incorporates the modulator IC package 100) and to generate, from the input voltage Vin, a supply voltage Vsup for the output stage circuitry 130. The power converter circuitry may comprise DC-DC buck or boost converter circuitry. For example, the power converter circuitry may comprise flyback converter circuitry, single-switch forward converter circuitry, two-switch forward converter circuitry, split rail forward converter circuitry or the like.

The power modulator circuitry 120 is configured to monitor the supply voltage Vsup output by the power converter circuitry 140, and to control the power converter circuitry 140, based at least in part on the supply voltage Vsup, e.g. to regulate the output supply voltage Vsup at a desired level. The power modulator circuitry 120 may be implemented in digital circuitry or in analog circuitry, or in a combination of digital and analog circuitry.

It can be beneficial for both the signal modulator circuitry 110 and the power modulator circuitry 120 to be implemented in digital circuitry, as this allows the use of a common clock and/or a single control interface for both the signal modulator circuitry 110 and the power modulator circuitry 120. This simplifies the design of the integrated circuit package 100 and control of the signal modulator circuitry 110 and the power modulator circuitry 120, permitting synchronisation between the signal modulator circuitry 110 and the power modulator circuitry 120, as well as facilitating resolution of issues such as electromagnetic interference (EMI), clock coupling and the like. Thus, the IC packages of the present disclosure may be configured such that the signal modulator circuitry 110 and the power modulator circuitry 120 receive a common clock signal. The signal modulator circuitry and the power modulator circuitry of the IC packages of the present disclosure may be configured to receive a common clock signal. The signal modulator circuitry and the power modulator circuitry may thus be described as being synchronously clocked. The common clock signal may be generated by clock generator circuitry that may be provide as part of the IC package, or may be external to the IC package.

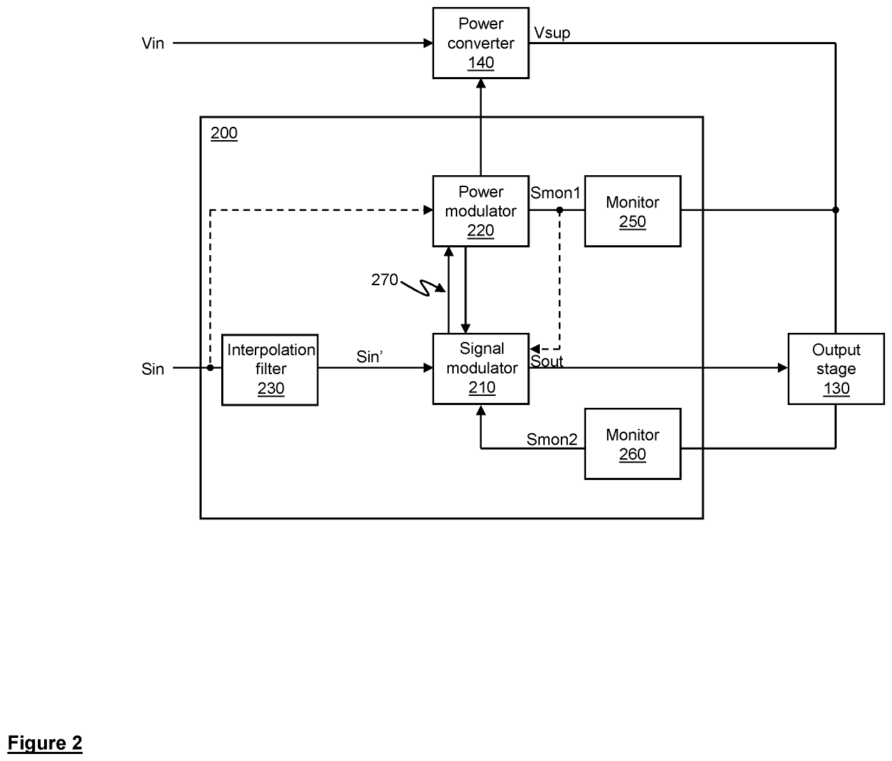

FIG. 2 is a schematic representation of another example modulator integrated circuit (IC) package. As in the modulator IC package 100 of FIG. 1, the modulator IC package 200 in the example illustrated in FIG. 2 includes signal modulator circuitry 210 and power modulator circuitry 220. In some examples the modulator IC package 200 is implemented in a single IC die, such that the signal modulator circuitry 210 and the power modulator circuitry 220 are integrated in a single IC die. In other examples, the signal modulator circuitry 210 may be implemented on a first IC die and the power modulator circuitry 220 may be implemented on a second IC die, with the first and second IC die being provided within the modulator IC package 200.

In this example the signal modulator circuitry 210 and the power modulator circuitry 220 are both implemented using digital circuitry.

In addition, the modulator IC package 200 in this example includes first monitor circuitry 250 and second monitor circuitry 260. The first monitor circuitry 250 has an input coupled to the output of the external power converter circuitry 140 and an output coupled to an input of the power modulator circuitry 220, and is configured to generate a first monitor output signal Smon1 indicative of the supply voltage Vsup output by the power converter circuitry 140. The first monitor circuitry 250 may comprise, for example, analog to digital converter (ADC) circuitry.

In some examples the output of the first monitor circuitry 250 is also coupled to an input of the signal modulator circuitry 210 to supply the first monitor output signal Smon1 to the signal modulator circuitry 210.

The power modulator circuitry 220 is operative to control the external power converter circuitry 140 based at least in part on the first monitor output signal Smon1. For example, if the first monitor output signal Smon1 is indicative that a magnitude of the supply voltage Vsup output by the power converter circuitry 140 is too low to support a required output voltage range of the output stage circuitry 130, the power modulator circuitry 220 may control the power converter circuitry 140 to increase the magnitude of the supply voltage Vsup, e.g. by increasing a duty cycle of the power converter circuitry 140.

In some examples, the signal modulator circuitry 210 is operative to control or adjust a parameter (e.g. a pulse width, duty cycle, peak signal amplitude, applied gain, compression or the like) of the modulated output signal Sout based, at least in part, on the first monitor output signal Smon1.

For example, if the first monitor output signal Smon1 is indicative that a magnitude of the supply voltage Vsup output by the power converter circuitry 140 is too low to support an output voltage (or output voltage range) of the output stage circuitry 130 required to generate an audio output signal based on the modulated output signal Sout without clipping or other distortion of the audio output signal, the signal modulator circuitry 210 may adjust or modify one or more characteristics or parameters of the modulated output signal Sout (e.g. a pulse width or duty cycle, in the case where the modulated output signal Sout is a pulse width modulated signal, or a peak signal amplitude or gain or compression applied to the modulated output signal Sout) such that an audio output of reduced amplitude is generated by the output stage circuitry 130, thereby avoiding clipping or other distortion in the audio output signal.

In some examples an output of the first monitor circuitry 250 is coupled to an input of the signal modulator circuitry 210, such that the first monitor output signal Smon1 is supplied to the signal modulator circuitry 210. In other examples, the power modulator circuitry 220 and the signal modulator circuitry 210 are configured to communicate with each other (e.g. via a bidirectional communications link 270 between the signal modulator circuitry 210 and the power modulator circuitry 220), such that the first monitor output signal Smon1 (or a signal representative or indicative of the first monitor output signal Smon1), can be transmitted by the power modulator circuitry 220 to the signal modulator circuitry 210.

The second monitor circuitry 260 has an input coupled to at least one node of the output stage circuitry 130 and an output coupled to the signal modulator circuitry 210. The second monitor circuitry 260 is configured to monitor one or more operational parameters of or associated with the output stage circuitry 130, e.g. a voltage or current of the output stage circuitry 130, an impedance of a transducer driven by the output stage circuitry 130, a thermal parameter (e.g. a coil temperature) of a transducer driven by the output stage circuitry 130 or the like, and to generate a second monitor output signal Smon2 indicative of the one or more operational parameters of or associated with the output stage circuitry 130.

The signal modulator circuitry 210 may be operative to control or adjust a parameter of the modulated output signal Sout based, at least in part, on the second monitor output signal Sout2. For example, if the second monitor output signal Smon2 is indicative that a fault or error condition exists, e.g. that an output transducer such as a speaker is approaching or has exceeded an operating threshold such as a speaker coil temperature threshold or a speaker excursion threshold (as may be detected, for example, based on a monitored voltage and/or current of the output stage circuitry 130), the signal modulator circuitry 210 may adjust or modify one or more characteristics or parameters of the modulated output signal Sout (e.g. a pulse width or duty cycle, in the case where the modulated output signal Sout is a pulse width modulated signal, or a peak signal amplitude or gain or compression applied to the modulated output signal Sout) such that an audio output of reduced amplitude is generated by the output stage circuitry 130, or may cease outputting the modulated output signal Sout, until the fault or error condition has been cleared.

In some examples the power modulator circuitry 220 is configured to receive the input signal Sin. Alternatively, the signal modulator circuitry 210 may be operative to supply the input signal Sin or a signal indicative of a characteristic or parameter of the input signal (e.g. a level or envelope of the input signal Sin) to the power modulator circuitry 220. In such examples the power modulator circuitry 220 may be operative to control the external power converter circuitry 140 based at least in part on the input signal Sin or the signal indicative of the characteristic or parameter of the input signal.

In one example, the power modulator circuitry 220 may be operative to control the external power converter circuitry 140 to modulate the supply voltage Vsup between two or more supply voltage levels based on the input signal Sin or the characteristic or parameter of the input signal Sin. Thus, if the level or envelope (for example) of the input signal Sin is below a first threshold, the power modulator circuitry 220 may control the external power converter circuitry 140 to cause it to output a supply voltage Vsup of a first magnitude Vsup1. If the level or envelope of the input signal Sin is between the first threshold and a second threshold that is higher than the first threshold, the power modulator circuitry 220 may control the external power converter circuitry 140 to cause it to output a supply voltage Vsup of a second magnitude Vsup2, where Vsup2 is greater than Vsup1. If the level or envelope of the input signal Sin exceeds the second threshold, the power modulator circuitry 220 may control the external power converter circuitry 140 to cause it to output a supply voltage Vsup of a third magnitude Vsup3, where Vsup3 is greater than Vsup2. Thus, in this example the power modulator circuitry 220 and the power converter circuitry 140 implement behaviour similar to that of a Class G amplifier.

In another example, the power modulator circuitry 220 may be operative to control the external power converter circuitry 140 to modulate the supply voltage Vsup based on the input signal Sin so as to maintain a fixed voltage difference between the supply voltage Vsup and the input voltage or between the supply voltage Vsup and an output voltage of the output stage circuitry 130. Thus, in this example the power modulator circuitry 220 and the power converter circuitry 140 implement behaviour similar to that of a Class H amplifier.

Modulating the supply voltage Vsup based on the input signal in this way may help to improve the efficiency of a host device or system incorporating the modulator IC package, the output stage circuitry 130 and the power converter circuitry 140, as unnecessary overhead in the supply voltage Vsup to the output stage circuitry 130 can be reduced or eliminated.

As will be appreciated by those of ordinary skill in the art, any change in the supply voltage Vsup based on the input signal Sin cannot be implemented instantaneously. Thus it may be desirable to implement a delay in the input signal Sin or the modulated output signal Sout, such that a change in the supply voltage Vsup coincides with a corresponding change in the modulated output signal Sout, to ensure that a supply voltage Vsup of a magnitude sufficient to support a desired output voltage of the output stage circuitry 130 is available.

In a practical implementation of the IC package 200, the signal modulator circuitry 210 will operate at a much higher sample rate than a sample rate of the input signal Sin, and thus the IC package 200 may include interpolation filter circuitry 230 configured to perform an interpolation function on the input signal Sin to generate an interpolated input signal Sin′, at a sample rate that matches that of the signal modulator circuitry 210, to output to the signal modulator circuitry 210. The interpolation filter circuitry 230 introduces a delay (typically of the order of 10 microseconds) between the interpolated input signal Sin′ and the input signal Sin. By monitoring the input signal Sin (rather than the interpolated input signal Sin′), the power modulator circuitry 220 is able to “look-ahead” ensure that the necessary or desired modulation of the supply voltage Vsup is achieved to coincide with the corresponding change in the modulated output signal Sout. Those of ordinary skill in the art will be familiar with other ways of implementing such “look-ahead” functionality.

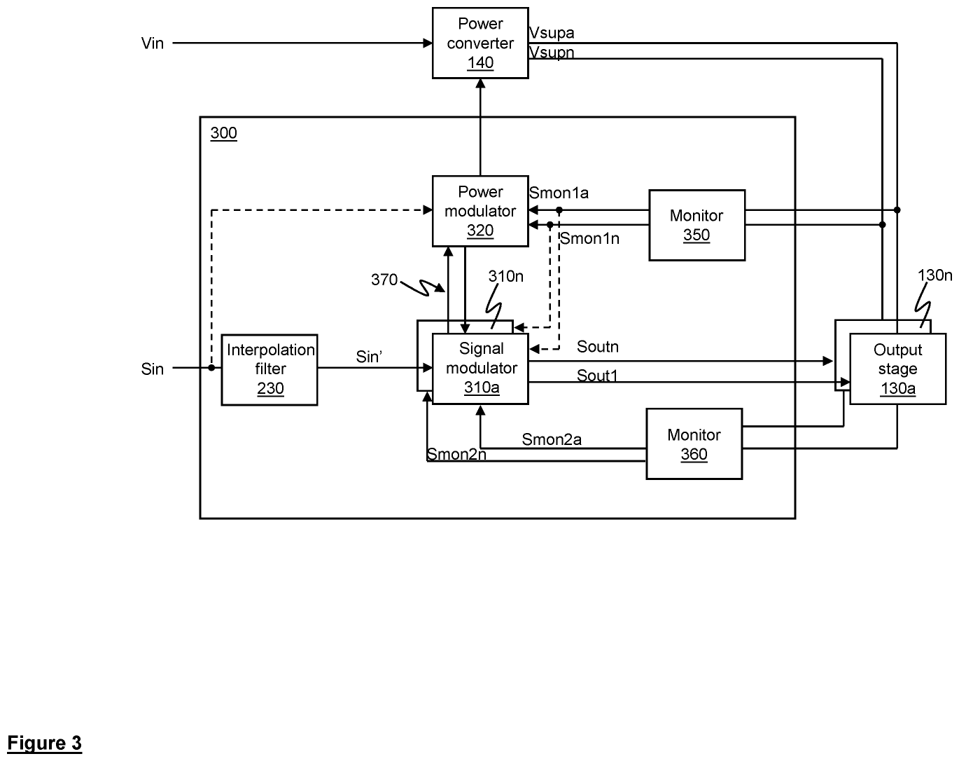

FIG. 3 is a schematic representation of a further example modulator integrated circuit (IC) package.

The modulator IC package 300 of FIG. 3 includes a plurality of instances 310a-310n of signal modulator circuitry, each configured to receive an input signal and to supply a respective modulated output signal Sout1-Soutn to a respective one of a plurality of instances of output stage circuitry 130a-130n external to the modulator IC package 300. The plurality of instances of external output stage circuitry 130a-130n may each be configured to drive a respective one of a plurality of output transducers, e.g. a respective speaker of a plurality of speakers in an audio system of a vehicle. As in the IC package 200 of FIG. 2, the IC package 300 may include interpolation filter circuitry 230 configured to receive an input signal Sin and output an interpolated input signal Sin′ at a sample rate that corresponds to a sample rate of each of the plurality of instances of signal modulator circuitry 310a-310n. d

The modulator IC package 300 also includes power modulator circuitry 320 configured to control operation of power converter circuitry 140 external to the modulator IC package 300. The external power converter circuitry 140 is configured, in this example, to provide a supply voltage to each of the plurality of instances of output stage circuitry 130a-130n. The power converter circuitry 140 may be configured to provide the same supply voltage (i.e. to provide a supply voltage Vsup of equal magnitude) to each of the instances of output stage circuitry 130a-130n. Alternatively, the power converter circuitry 140 may be configured to provide a different supply voltage (i.e. to provide supply voltages Vsupa-Vsupn of different magnitude) to each respective instance of output stage circuitry 130a-130n.

The modulator IC package 300 further includes first monitor circuitry 350 and second monitor circuitry 360. The first monitor circuitry 350 is configured to generate one or more first monitor output signals Smon1a-Smon1n indicative of the supply voltage(s) output by the power converter circuitry 140.

In some examples, the first monitor circuitry 350 has a plurality of inputs, each coupled to a respective output of the power converter circuitry 140 so as to receive a respective one of the supply voltages Vsupa-Vsupn output by the power converter circuitry 140. In other examples, the first monitor circuitry 350 may have a single input that is multiplexed between the outputs of the power converter circuitry 140 (e.g. on a time division basis). Similarly, the first monitor circuitry 350 in some examples has a plurality of outputs, each coupled to a respective input of the power modulator circuitry 320 so as to supply a respective first monitor output signal Smon1a-Smon1n to the power modulator circuitry 320. In other examples, the first monitor circuitry 350 may have a single output coupled to an input of the power modulator circuitry 320, with the first monitor output signals Smon1a-Smon1n being supplied to the power modulator circuitry 320 on a time division multiplexed basis. In a further alternative example, the modulator IC package 300 may include a plurality of instances of first monitor circuitry, each having an input coupled to a respective output of the power converter circuitry 140 and an output coupled to a respective input of the power modulator circuitry 320. The first monitor circuitry 350 may comprise, for example, ADC circuitry.

In some examples one or more of the outputs of the first monitor circuitry 350 are also coupled to a respective one or more of inputs of the signal modulator circuitry 310 to supply the first monitor output signals Smon1a-Smon1n to the signal modulator circuitry 310.

The power modulator circuitry 320 is operative to control the external power converter circuitry 140 based at least in part on one or more of the first monitor output signals Smon1a-Smon1n. For example, if a first monitor output signal Smon1a is indicative that a magnitude of the supply voltage Vsupa output by the power converter circuitry 140 is too low to support a required output voltage range of a first instance 130a of output stage circuitry, the power modulator circuitry 320 may control the power converter circuitry 140 to increase the magnitude of the supply voltage Vsupa output to the first instance 130a of output stage circuitry, without changing the magnitude of the supply voltage output to any of the other instances of output stage circuitry.

In some examples, the signal modulator circuitry 310 is operative to control or adjust a parameter of the modulated output signal Sout based, at least in part, on one or more of the first monitor output signals Smon1a-Smon1n. For example, if a first monitor output signal Smon1a is indicative that a magnitude of the supply voltage Vsupa output by the power converter circuitry 140 is too low to support an output voltage (or output voltage range) of a first instance 130a of output stage circuitry required to generate an audio output signal based on a first modulated output signal Souta without clipping or other distortion of the audio output signal, the signal modulator circuitry 310 may adjust or modify one or more characteristics or parameters of the first modulated output signal Souta (e.g. a pulse width or duty cycle, in the case where the first modulated output signal Souta is a pulse width modulated signal, or a peak signal amplitude or gain or compression applied to the first modulated output signal Souta) such that an audio output of reduced amplitude is generated by the first instance 130a of output stage circuitry, thereby avoiding clipping or other distortion in the audio output signal.

In some examples one or more outputs of the first monitor circuitry 350 are coupled to one or more inputs of the signal modulator circuitry 310, such that the first monitor output signals Smon1a-Smon1n are supplied to the signal modulator circuitry 310. In other examples, the power modulator circuitry 320 and the signal modulator circuitry 310 are configured to communicate with each other (e.g. via a bidirectional communications link 370 between the signal modulator circuitry 310 and the power modulator circuitry 320), such that the first monitor output signals Smon1a-Smon1n (or signals representative or indicative of the first monitor output signals Smon1a-Smon1n), can be transmitted by the power modulator circuitry 320 to the signal modulator circuitry 310.

The second monitor circuitry 360 is configured to generate one or more second monitor output signals Smon2a-Smon2n indicative of one or more operational parameters of or associated with respective instances 130a-130n of output stage circuitry.

In some examples, the second monitor circuitry 360 has a plurality of inputs, each coupled to a node of a respective instance 130a-130n of output stage circuitry. In other examples, the second monitor circuitry 360 may have a single input that is multiplexed between a respective node of each instance 130a-130n of output stage circuitry (e.g. on a time division basis). Similarly, the second monitor circuitry 360 in some examples has a plurality of outputs, each coupled to an input of a respective instance 310a-310n of signal modulator circuitry so as to supply a respective second monitor output signal Smon2a-Smon2n to the respective instance 310a-310n of signal modulator circuitry. In other examples, the second monitor circuitry 360 may have a single output coupled to an input of each of the plurality of instances 310a-310n of signal modulator circuitry, with the second monitor output signals Smon2a-Smon2n being supplied to the respective instances of signal modulator circuitry 310 on a time division multiplexed basis. In a further alternative example, the modulator IC package 300 may include a plurality of instances of second monitor circuitry, each having an input coupled to a node of a respective instance 130a-310n of output stage circuitry and an output coupled to an input of a respective instance 310a-310n of signal modulator circuitry.

The second monitor circuitry 360 is configured to monitor one or more operational parameters of or associated with one or more of the instances 130a-130n of output stage circuitry, e.g. a voltage or current of an instance of output stage circuitry, an impedance of a transducer driven by an instance of output stage circuitry, a thermal parameter (e.g. a coil temperature) of a transducer driven by an instance of output stage circuitry 130 or the like, and to generate one or more second monitor output signals Smon2a-Smon2n indicative of the one or more monitored operational parameters.

The relevant instance 310a-310n of signal modulator circuitry may be operative to control or adjust a parameter of its modulated output signal Sout1-Soutn based, at least in part, on the relevant one of the second monitor output signals Sout2a-Sout2n. For example, if a second monitor output signal Smon2a is indicative that a fault or error condition exists, e.g. that an output transducer such as a speaker driven by a first instance 130a of output stage circuitry is approaching or has exceeded an operating threshold such as a speaker coil temperature threshold or a speaker excursion threshold (as may be detected, for example, based on a monitored voltage and/or current of the first instance 130a of output stage circuitry), the first instance 310a of signal modulator circuitry may adjust or modify one or more characteristics or parameters of its modulated output signal Souta (e.g. a pulse width or duty cycle, in the case where the modulated output signal Souta is a pulse width modulated signal, or a peak signal amplitude or gain or compression applied to the modulated output signal Souta) such that an audio output of reduced amplitude is generated by the first instance 130a of output stage circuitry 130, or may cease outputting the modulated output signal Souta, until the fault or error condition has been cleared.

As in the example modulator IC package 200 of FIG. 2, in some examples the power modulator circuitry 320 is configured to receive the input signal Sin. Alternatively, an instance 310a-310n of the signal modulator circuitry may be operative to supply the input signal Sin or a signal indicative of a characteristic or parameter of the input signal (e.g. a level or envelope of the input signal Sin) to the power modulator circuitry 320. In such examples the power modulator circuitry 320 may be operative to control the external power converter circuitry 140 based at least in part on the input signal Sin or the signal indicative of the characteristic or parameter of the input signal Sin.

In one example, the power modulator circuitry 320 may be operative to control the external power converter circuitry 140 to modulate one or more of the supply voltages Vsupa-Vsupn between two or more supply voltage levels based on the input signal Sin or the characteristic or parameter of the input signal Sin. Thus, if the level or envelope (for example) of the input signal Sin is below a first threshold, the power modulator circuitry 320 may control the external power converter circuitry 140 to cause it to output one or more supply voltages Vsupa-Vsupn of a first magnitude Vsup1. If the level or envelope of the input signal Sin is between the first threshold and a second threshold that is higher than the first threshold, the power modulator circuitry 320 may control the external power converter circuitry 140 to cause it to output one or more supply voltages Vsupa-Vsupn of a second magnitude Vsup2, where Vsup2 is greater than Vsup1. If the level or envelope of the input signal Sin exceeds the second threshold, the power modulator circuitry 320 may control the external power converter circuitry 140 to cause it to output one or more supply voltages Vsupa-Vsupn of a third magnitude Vsup3, where Vsup3 is greater than Vsup2. Thus, in this example the power modulator circuitry 320 and the power converter circuitry 140 implement behaviour similar to that of a Class G amplifier.

In another example, the power modulator circuitry 320 may be operative to control the external power converter circuitry 140 to modulate one or more of the supply voltages Vsupa-Vsupn based on the input signal Sin so as to maintain a fixed voltage difference between the supply voltage(s) and the input voltage or between the supply voltage(s) and an output voltage of the output stage circuitry 130. Thus, in this example the power modulator circuitry 320 and the power converter circuitry 140 implement behaviour similar to that of a Class H amplifier.

In some examples, the power modulator circuitry 320 may be operative to control the supply voltages Vsupa-Vsupn output to individual instances 130a-130n based at least in part on the input signal Sin. For example, if the input signal Sin contains frequency components of high amplitude (e.g. representing loud bass frequencies, in the case where the input signal Sin an audio signal), the power modulator circuitry 320 may be operative to control the power converter circuitry 140 such that the supply voltage output by the power converter circuitry 140 to an instance of output stage circuitry that drives a particular output transducer (e.g. a woofer) is greater than the supply voltage output to instances of output stage circuitry that drive other output transducers (e.g. tweeters).

Thus, the supply voltage output to each instance 130a-130n of output stage circuitry, and the modulated output signal Sout1-Soutn output to each instance 130a-130n of output stage circuitry can be controlled based on one or more parameters or characteristics of the input signal and/or based on one or more operational parameters of the output stage circuitry and/or based on the supply voltage to each instance 130a-130n of output stage circuitry. This allows the operation of the modulator IC package 300 to be controlled or adjusted to optimise or improve characteristics such as power consumption, output signal amplitude, output distortion and the like, and/or to manage trade-offs between such characteristics to achieve a desired or optimum level of performance of the modulator IC package 300 and/or a host device or system incorporating the modulator IC package 300.

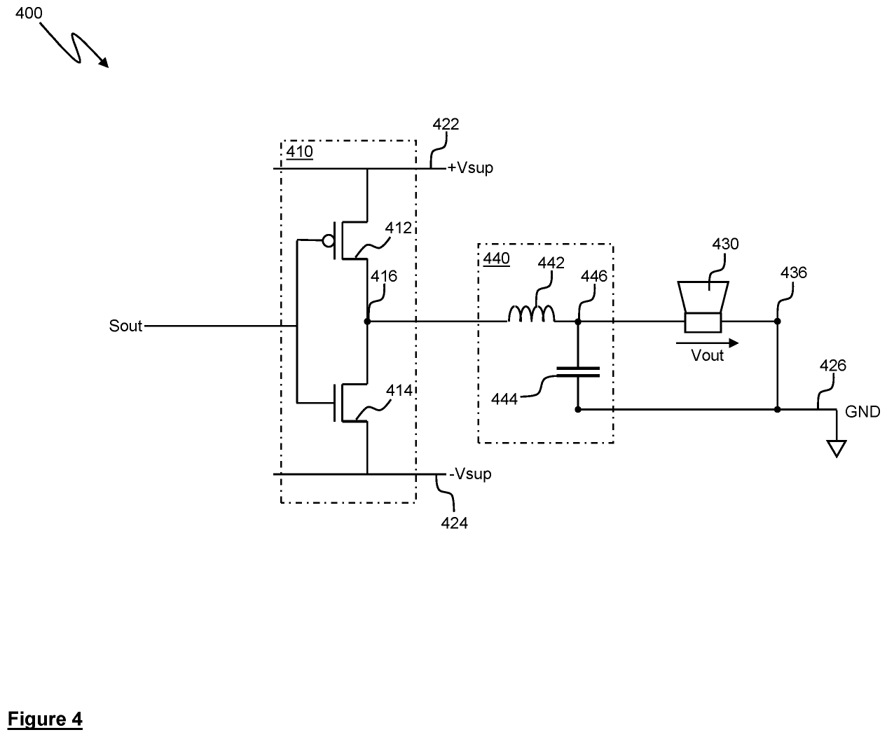

FIG. 4 is a schematic representation of example single-ended output stage circuitry for use as the output stage circuitry (or as an instance of output stage circuitry) with the modulator IC packages 100, 200, 300 described above with reference to FIGS. 1-3.

The single-ended output stage circuitry, shown generally at 400 in FIG. 4, comprises a half-bridge 410 having a high-side switch 412 coupled in series with a complementary low-side switch 414 between a first supply voltage rail 422 (which receives a first, positive, supply voltage +Vsup from the power converter circuitry 140) and a second supply voltage rail 424 (which in the illustrated example receives a second, negative, supply voltage −Vsup from the power converter circuitry 140, but which could, in other examples, receive a 0V/ground or other reference voltage supply) of the single-ended output stage circuitry 400. The high-side switch 412 and the low-side switch 414 may be, for example, complementary MOSFET devices.

Alternatively, the high-side switch 412 and the low-side switch 414 may be wide bandgap devices or high electron mobility transistor (HEMT) devices based on, for example, Gallium Nitride (GaN), Silicon Carbide (SIC), Gallium Oxide (Ga₂0₃) or other semiconductor materials. Such devices are typically capable of operation at higher voltages, higher temperatures and higher frequencies than silicon-based switches such as MOSFETs, and so for high power applications (e.g. applications in which the output power is equal to or greater than 50 W) may provide a more cost-effective solution than silicon-based devices. The circuit area occupied by the switches 412, 414 in output stage circuitry of the kind shown in FIG. 4 may be minimised or at least reduced by using switches having higher resistance.

In use of the single-ended output stage circuitry 400, a load 430 such as a loudspeaker is coupled between an output node 416 of the half-bridge 410 and a reference voltage (e.g. ground) rail 426 of the single-ended output stage circuitry 400. In the example shown in FIG. 4, output filter circuitry 440, in the form of low-pass filter circuitry comprising an inductor 442 and a capacitor 444, is coupled between the output node 416 and the load 430, to attenuate high frequency components that may be present in an output signal of the half-bridge 410 due to the switching frequency of the switches 412, 414.

In operation of the single-ended output stage circuitry 400, a modulated output signal Sout, e.g. output by the signal modulator circuitry 110, 210 or an instance 310a-310n of signal modulator circuitry is supplied to control terminals (e.g. gate terminals) of the high-side switch 412 and low-side switch 414 of the half-bridge 410. As will be appreciated by those of ordinary skill in the art, the modulated output signal Sout is arranged such that when the high-side switch 412 is switched on in response to a control signal at its control terminal, the low-side switch 414 is switched off, and vice versa. Thus, in operation of the half-bridge 410, the output node 416 will be at either the first supply voltage (+Vsup) or the second supply voltage (−Vsup), depending upon whether the high-side switch 412 or the low-side switch 414 is switched on. The output voltage Vout across the load 430 can thus take one of two levels: +Vsup or −Vsup.

In some examples the single-ended output stage circuitry 400 may be implemented in integrated circuitry (e.g. as a single integrated circuit, separate from the modulator IC package 100, 200, 300 that supplies the modulated output signal Sout, incorporating the high-side switch 412 and the low-side switch 414), but the output filter circuitry 440 is typically implemented using discrete components that are not implemented in integrated circuitry—i.e. the inductor 442 and capacitor 444 of the output filter circuitry 440 are typically off-chip devices. However, in other examples the single-ended output stage circuitry 400 may be implemented entirely using off-chip devices, particularly in high-power applications where the cost of on-chip switches may be greater than that of off-chip switches.

As noted above, the second monitor circuitry 260 of the modulator IC package 200 described above with reference to FIG. 2 and the second monitor circuitry 360 of the modulator IC package 300 described above with reference to FIG. 3 are configured to monitor one or more operational parameters of or associated with the output stage circuitry 130, e.g. a voltage or current of the output stage circuitry 130, an impedance of a transducer driven by the output stage circuitry 130, a thermal parameter (e.g. a coil temperature) of a transducer driven by the output stage circuitry 130 or the like.

To this end, in use of the single-ended output stage circuitry 400 in conjunction with the modulator IC package 200 or the modulator IC package 300, an input of the second monitor circuitry 260, 360 may be coupled to the output node 416 of the half-bridge 410 such that the second monitor circuitry 260, 360 can monitor an output voltage and/or an output current of the half-bridge 410. Additionally or alternatively, an input of the second monitor circuitry may be coupled to a filter output node 446, which in the illustrated example is a node between the inductor 442 and the capacitor 444 of the output circuitry 440, such that the second monitor circuitry 260, 360 can monitor an output voltage and/or an output current of the output filter circuitry 440. Additionally or alternatively, an input of the second monitor circuitry may be coupled to a node 436 between the load 430 and the reference voltage rail 426, such that the second monitor circuitry 260, 360 can monitor voltage across and/or a current through the load 430.

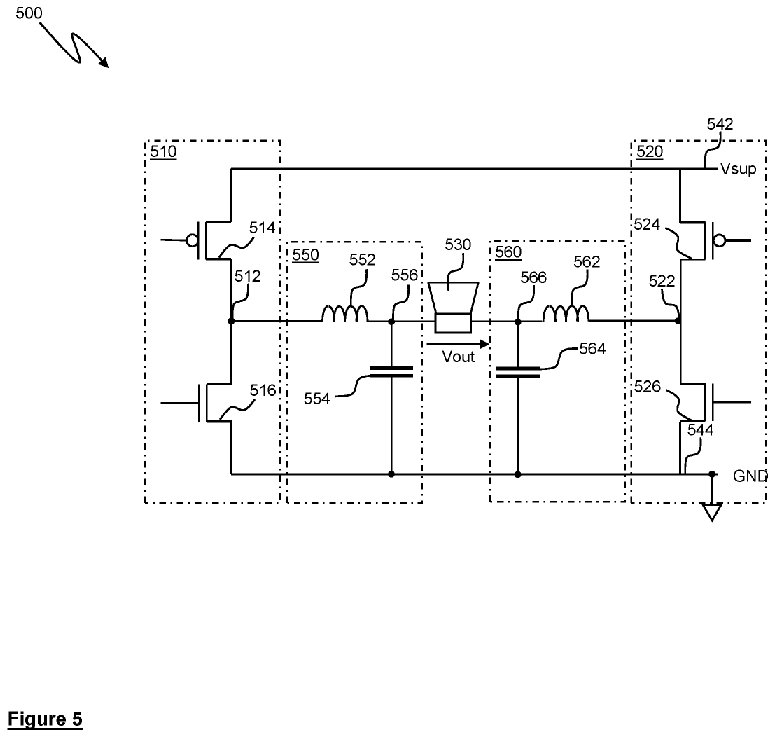

FIG. 5 is a schematic representation of full bridge differential output stage circuitry for use as the output stage circuitry (or as an instance of output stage circuitry) with the modulator IC packages 100, 200, 300 described above with reference to FIGS. 1-3.

The full bridge differential output stage circuitry, shown generally at 500 in FIG. 5, comprises a first half-bridge 510 and a second half-bridge 520, which together provide a differential output voltage Vout for driving a bridge-tied load 530 (e.g. a loudspeaker) that can be coupled between respective output nodes 512, 522 of the first and second half-bridges 510, 520.

The first half-bridge 510 comprises a high-side switch 514 coupled in series with a complementary low-side switch 516 between a first supply voltage rail 542 (which receives a positive supply voltage Vsup from the power converter circuitry 140) and a reference voltage (e.g. ground) rail 544 of the output stage circuitry 500. The high-side switch 514 and the low-side switch 516 may be, for example, complementary MOSFET devices, or alternatively may be wide bandgap devices or high electron mobility transistor (HEMT) devices based on, for example, Gallium Nitride (GaN), Silicon Carbide (SiC), Gallium Oxide (Ga₂0₃) or other semiconductor materials.

Similarly, the second half-bridge 520 comprises a high-side switch 524 coupled in series with a complementary low-side switch 526 between the first supply voltage rail 542 and the reference voltage (e.g. ground) rail 544 of the output stage circuitry 500. Again, the high-side switch 124 and the low-side switch 126 may be, for example, complementary MOSFET devices, or alternatively may be wide bandgap devices or high electron mobility transistor (HEMT) devices based on, for example, Gallium Nitride (GaN), Silicon Carbide (SiC), Gallium Oxide (Ga₂0₃) or other semiconductor materials.

First output filter circuitry 550, which in this example is low-pass filter circuitry comprising an inductor 552 and a capacitor 554 is coupled between the output node 512 of the first half-bridge 510 and a first load terminal to which a first terminal of the load 530 is coupled in use of the full bridge differential output stage circuitry 500. Similarly, second low-pass filter circuitry 560, in this example comprising an inductor 562 and a capacitor 564 is coupled between the output node 522 of the second half-bridge 520 and a second load terminal to which a second terminal of the load 530 is coupled in use of the full bridge differential output stage circuitry 500.

In use of the output stage circuitry 500, control signals such as pulse width modulated (PWM) signals based on the modulated output signal Sout output by the signal modulator circuitry 110, 210 or an instance 310a-310n of modulator circuitry are supplied to control terminals (e.g. gate terminals) of the high-side switch 514 and low-side switch 516 of the first half-bridge 510, and to control terminals (e.g. gate terminals) of the high-side switch 524 and the low-side switch 526 of the second half-bridge 520. The control signals are arranged such that when the high-side switch 514 is switched on in response to a control signal at its control terminal, the low-side switch 516 is switched off, and vice versa. Thus, in operation of the first half-bridge 510, the output node 512 will be at either the supply voltage (Vsup) or the reference voltage (e.g. ground), depending upon whether the high-side switch 514 or the low-side switch 516 is switched on. Similarly, in operation of the second half-bridge 520, the output node 522 will be at either the first supply voltage (Vsup) or the reference voltage (e.g. ground), depending upon whether the high-side switch 524 or the low-side switch 526 is switched on. The output voltage Vout across the load 530 can thus take any of three levels: +Vsup, −Vsup or 0V (assuming that the reference voltage rail 544 is coupled to ground).

In some examples (e.g. low-power applications), the full bridge differential output stage circuitry 500 may be implemented in integrated circuitry (e.g. in a single integrated circuit) comprising the switches 514, 516, 524, 526 of the first and second half-bridges 510, 520, but the output filter circuitry 550, 560 is typically implemented using discrete components that are not implemented in integrated circuitry—i.e. the inductors 552, 562 and capacitors 554, 564 of the output filter circuitry 550, 560 are typically off-chip devices. However, in other examples, the full bridge differential output stage 500 may be implemented entirely using off-chip devices, particularly in high-power applications (e.g. where the output power is equal to or greater than 50 W) where the cost of on-chip switches may be greater than that of off-chip switches.

As noted above, the second monitor circuitry 260 of the modulator IC package 200 described above with reference to FIG. 2 and the second monitor circuitry 360 of the modulator IC package 300 described above with reference to FIG. 3 are configured to monitor one or more operational parameters of or associated with the output stage circuitry 130.

To this end, in use of the full bridge differential output stage 500 in conjunction with the modulator IC package 200 or the modulator IC package 300, an input of the second monitor circuitry 260, 360 may be coupled to the output node 512 of the first half-bridge 510 such that the second monitor circuitry 260, 360 can monitor an output voltage and/or an output current of the first half-bridge 510. Additionally or alternatively, an input of the second monitor circuitry 260, 360 may be coupled to the output node 522 of the second half-bridge 520 such that the second monitor circuitry 260, 360 can monitor an output voltage and/or an output current of the second half-bridge 520.

Additionally or alternatively, an input of the second monitor circuitry may be coupled to a filter output node 556 of the first output filter circuitry 550, which in the illustrated example is a node between the inductor 552 and the capacitor 554 of the first output filter circuitry 550, such that the second monitor circuitry 260, 360 can monitor an output voltage and/or an output current of the first output filter circuitry 550. Additionally or alternatively, an input of the second monitor circuitry may be coupled to a filter output node 566 of the second low-pass filter circuitry 560, which in the illustrated example is a node between the inductor 562 and the capacitor 564 of the second low-pass filter circuitry 560, such that the second monitor circuitry 260, 360 can monitor an output voltage and/or an output current of the second low-pass filter circuitry 560.

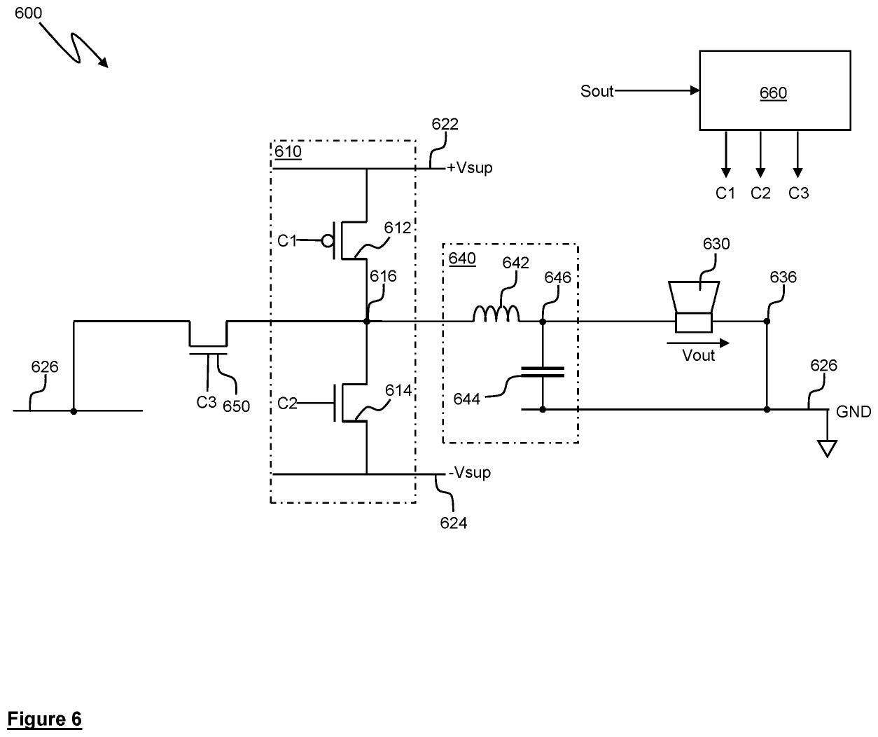

FIG. 6 is a schematic representation of example multi-level single-ended output stage circuitry for use as the output stage circuitry (or as an instance of output stage circuitry) with the modulator IC packages 100, 200, 300 described above with reference to FIGS. 1-3.

The multi-level single-ended output stage circuitry, shown generally at 600 in FIG. 6 comprises a half-bridge 610 comprising a high-side switch 612 and a low-side switch 614 coupled in series between a first power supply rail 622 (which receives a positive power supply voltage +Vsup from the power converter circuitry 140) and a second power supply rail 624 (which in this example receives a negative power supply voltage −Vsup from the power converter circuitry 140, but which could, in other examples, receive a 0V/ground or other reference voltage supply), with an output node 616 of the half-bridge 610 being coupled, via output filter circuitry 640 (which in this example is low-pass filter circuitry comprising an inductor 642 and a capacitor 644) to a first terminal of a load 630, the load 630 having a second terminal coupled to a reference voltage (e.g. ground) rail 626.

The multi-level single-ended output stage circuitry 600 of FIG. 6 further comprises a third switch 650, having an input terminal coupled to an intermediate supply voltage rail that supplies a voltage of a magnitude between the positive supply voltage +Vsup and the reference voltage. In this example the input terminal is coupled to the reference voltage (e.g. ground) rail 626) so as to supply a voltage between +Vsup and −Vsup. The multi-level single-ended output stage circuitry 600 further includes an output terminal coupled to the output node 616 of the half-bridge 610.

The multi-level single-ended output stage circuitry 600 of FIG. 6 is configured for operation with relatively high output power, e.g. for applications where the output power is equal to or greater than 50 W. The high-side switch 612 and the low-side switch 614 are thus configured for operation at such voltages. In some examples the high-side switch 612 and the low-side switch 614 may be wide bandgap devices or high electron mobility transistor (HEMT) devices based on, for example, Gallium Nitride (GaN), Silicon Carbide (SiC), Gallium Oxide (Ga₂0₃) or other semiconductor materials.

The multi-level single-ended output stage circuitry 600 further comprises control circuitry 660 configured to control operation of the multi-level single-ended output stage circuitry 600.

The control circuitry 660 may comprise logic circuitry for generating control signals C1, C2, C3 from the modulated output signal Sout output by the signal modulator circuitry 110 of the modulator IC package 100, the signal modulator circuitry 210 of the modulator IC package 200, or by an instance 310a-310n of signal modulator circuitry of the modulator IC package 300.

In use of the multi-level single-ended output stage circuitry 600, control signals C1, C2, C3 are supplied by the control circuitry 660 to control terminals of the high-side switch 612, the low-side switch 614 and the third switch 650 respectively. The control signals C1, C2, C3 are arranged such that only one of the high-side switch 612, the low-side switch 614 and the third switch 650 can be switched on at once, so the output voltage Vout across the load 630 may take one of three values: +Vsup (when the high-side switch 612 is switched on and the low-side switch 614 and the third switch 650 are both switched off), −Vsup (when the low-side switch 614 is switched on and the high-side switch 612 and the third switch 650 are both switched off), or 0V (when the high-side switch 612 and the low-side switch 614 are both switched off and the third switch 650 is switched on). These three output voltage values may be used to encode three different values. For example, an output voltage of +Vsup may represent a value of +1, an output voltage of −Vsup may represent a value of −1 and an output voltage of 0 may represent a value of 0.

In some examples (e.g. low-power applications), the half-bridge 610 and the third switch 650 may be implemented in integrated circuitry (e.g. in a single integrated circuit) comprising the switches 612, 614 of the half-bridges 610 and the third switch 650, but the output filter circuitry 640 is typically implemented using discrete components that are not implemented in integrated circuitry—i.e. the inductor 642, and capacitor 644 of the output filter circuitry 640 are typically off-chip devices. However, in other examples, multi-level single-ended output stage circuitry 600 may be implemented entirely using off-chip devices, particularly in high-power applications (e.g. where the output power is equal to or greater than 50 W) where the cost of on-chip switches may be greater than that of off-chip switches.

As noted above, the second monitor circuitry 260 of the modulator IC package 200 described above with reference to FIG. 2 and the second monitor circuitry 360 of the modulator IC package 300 described above with reference to FIG. 3 are configured to monitor one or more operational parameters of or associated with the output stage circuitry 130.

To this end, in use of the multi-level single-ended output stage circuitry 600 in conjunction with the modulator IC package 200 or the modulator IC package 300, an input of the second monitor circuitry 260, 360 may be coupled to the output node 616 of the half-bridge 610 such that the second monitor circuitry 260, 360 can monitor an output voltage and/or an output current of the half-bridge 610. Additionally or alternatively, an input of the second monitor circuitry 260, 360 may be coupled to a filter output node 646 of the low-pass filter circuitry 640, which in the illustrated example is a node between the inductor 622 and the capacitor 644 of the low-pass filter circuitry 640, such that the second monitor circuitry 260, 360 can monitor an output voltage and/or an output current of the low-pass filter circuitry 640. Additionally or alternatively, an input of the second monitor circuitry may be coupled to a node 636 between the load 630 and the reference voltage supply rail 626, such that the second monitor circuitry 260, 360 can monitor a voltage across or a current through the load 630.

The single-ended output stage circuitry 400 of FIG. 4, the full-bridge differential output stage circuitry 500 of FIG. 5 and the multi-level output stage circuitry 600 of FIG. 6 are just three examples of possible implementations of the output stage circuitry 130. Those of ordinary skill in the art will readily appreciate that different switched output stage circuitry could equally be used to implement the output stage circuitry 130.

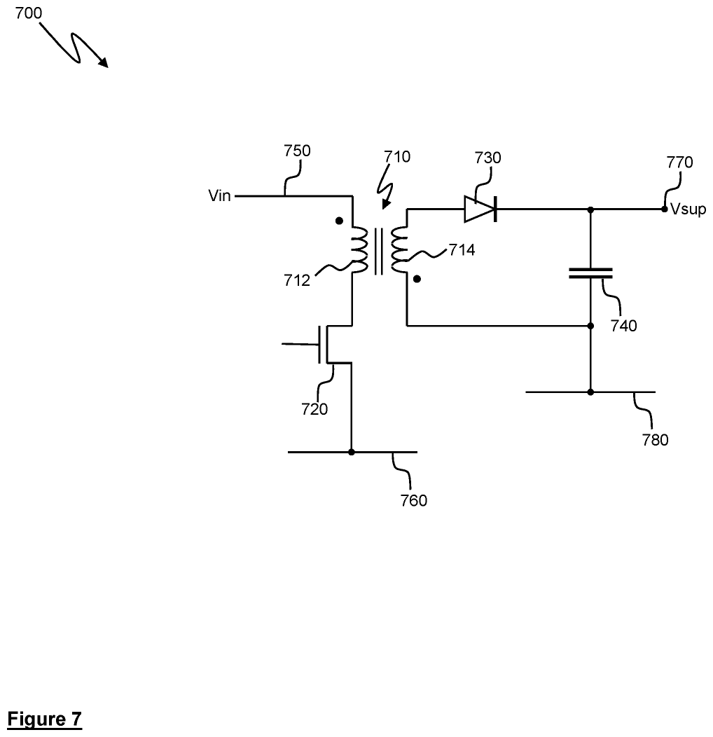

FIG. 7 is a schematic representation of example DC-DC converter circuitry suitable for use as the power converter circuitry 140. In this example the power converter circuitry, shown generally at 700 in FIG. 7, implements a flyback converter architecture.

The power converter circuitry 700 includes a transformer 710, a power switch 720, a diode 730 and an output capacitor 740. The power switch 720 may be, for example, a MOSFET device or a wide bandgap devices or high electron mobility transistor (HEMT) devices based on, for example, Gallium Nitride (GaN), Silicon Carbide (SiC), Gallium Oxide (Ga₂0₃) or other semiconductor materials.

A primary winding 712 of the transformer 710 is coupled in series between an input voltage rail 750, which receives an input voltage Vin (e.g. from a battery or other power supply of a host device) and a first terminal of the power switch 720. A second terminal of the power switch 720 is coupled to a reference voltage (e.g. ground) supply rail 760.

An anode of the diode 730 is coupled to a first terminal of a secondary winding 714 of the transformer 710. A cathode of the diode 730 is coupled to an output node 770 that can be coupled to the output stage circuitry to provide the supply voltage Vsup to the output stage circuitry 130.

A second terminal of the secondary winding 714 of the transformer 710 is coupled to a reference voltage (e.g. ground) supply rail 760. The output capacitor 740 is coupled in parallel with the secondary winding 714 of the transformer 710 between the cathode of the diode 730 and the reference voltage supply rail 760.

In operation of the power converter circuitry 700, a control signal (e.g. a PWM signal) is received at a control terminal (e.g. a gate terminal) of the power switch 720 from the power modulator circuitry 120, 220, 320 of the modulator IC package 100, 200, 300. This control signal controls a duty cycle of the power switch 720 and thus controls a current through the primary winding 712 of the transformer 710, thereby controlling the magnitude of the output voltage Vsup of the power converter circuitry 700 in a manner that will be familiar to those of ordinary skill in the art. The output voltage Vsup is monitored by the power modulator circuitry 120, 220, 320, either directly or via the output of the first monitor circuitry 250, 350.

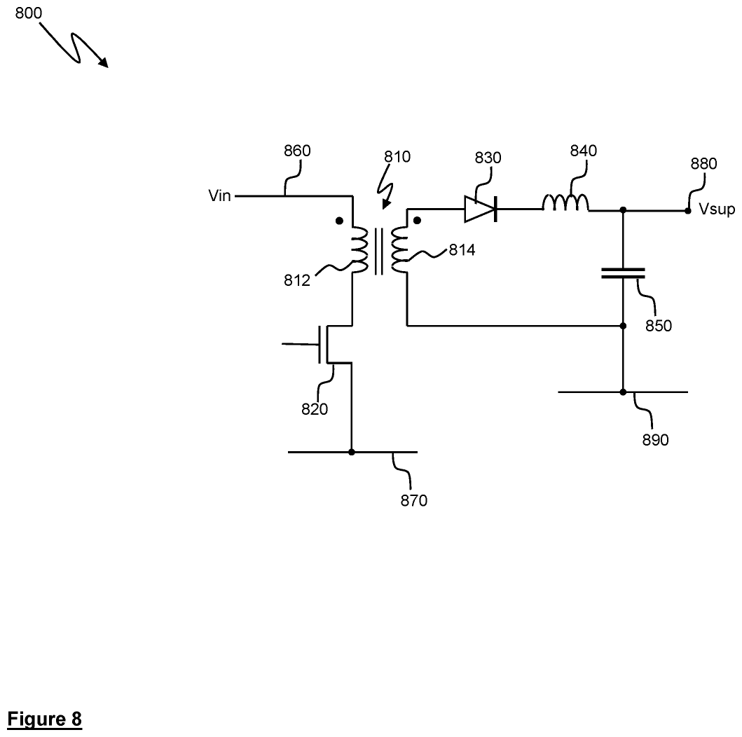

FIG. 8 is a schematic representation of further example DC-DC converter circuitry. In this example the power converter circuitry, shown generally at 800 in FIG. 8, implements a forward converter architecture.

The power converter circuitry 800 includes a transformer 810, a power switch 820, a diode 830, an inductor 840 and an output capacitor 850. The power switch 820 may be, for example, a MOSFET device or a wide bandgap devices or high electron mobility transistor (HEMT) devices based on, for example, Gallium Nitride (GaN), Silicon Carbide (SiC), Gallium Oxide (Ga₂0₃) or other semiconductor materials.

A primary winding 812 of the transformer 810 is coupled in series between an input voltage rail 860, which receives an input voltage Vin (e.g. from a battery or other power supply of a host device) and a first terminal of the power switch 820. A second terminal of the power switch 820 is coupled to a reference voltage (e.g. ground) supply rail 870.

An anode of the diode 830 is coupled to a first terminal of a secondary winding 814 of the transformer 810. A cathode of the diode 830 is coupled to a first terminal of the inductor 840, and a second terminal of the inductor 840 is coupled to an output node 880 which can be coupled to the output stage circuitry 130 to supply the output voltage Vsup to the output stage circuitry 130.

A second terminal of the secondary winding 814 of the transformer 810 is coupled to a reference voltage (e.g. ground) supply rail 890. The output capacitor 850 is coupled in parallel with the secondary winding 814 of the transformer 810 between the second terminal of the inductor 840 and the reference voltage supply rail 890.

In operation of the power converter circuitry 800, a control signal (e.g. a PWM signal) is received at a control terminal (e.g. a gate terminal) of the power switch 820 from the power modulator circuitry 120, 220, 320 of the modulator IC package 100, 200, 300. This control signal controls a duty cycle of the power switch 820 and thus controls a current through the primary winding 812 of the transformer 810, thereby controlling the magnitude of the output voltage Vsup of the power converter circuitry 800 in a manner that will be familiar to those of ordinary skill in the art. The output voltage Vsup is monitored by the power modulator circuitry 120, 220, 320, either directly or via the output of the first monitor circuitry 250, 350.

The flyback converter architecture of FIG. 7 and the forward converter architecture of FIG. 8 are just two examples of circuitry suitable for use as the power converter circuitry 140. Those of ordinary skill in the art will readily appreciate that other switched converter architectures, including (but not limited to) two-switch forward converters, split rail forward converters and the like, could equally be used to implement the power converter circuitry.

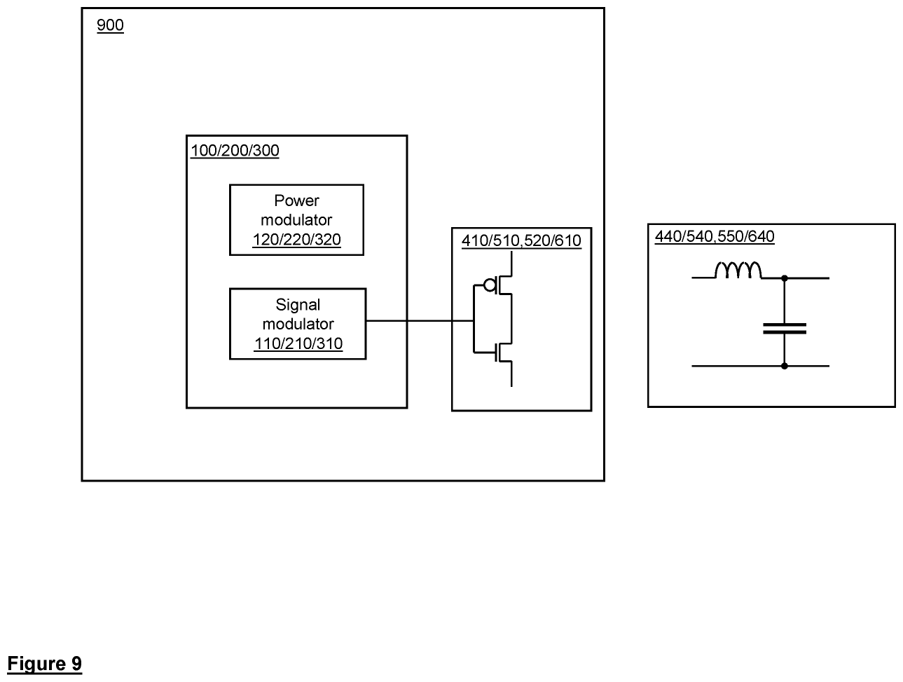

FIG. 9 is a schematic representation of a module comprising a modulator integrated circuit of the kind described above with reference to FIGS. 1-3 and switches of output stage circuitry.

The module, shown generally at 900 in FIG. 9, includes a modulator IC package 100, 200, 300 of the kind described above that includes power modulator circuitry 120, 220, 320 and one or more instances of signal modulator circuitry 110, 210, 310.

The module 900 further includes switches of output stage circuitry 130. For example, the module 900 may include the half-bridges 410, 510, 520, 610 of the output stage circuitry 400, 500, 600 described above with reference to FIGS. 4-6. However, the inductors and capacitors of the output filter circuitry 440, 540, 550, 640 of the output stage circuitry 400, 500, 600 of FIGS. 4-6 are not included in the module 900. Instead, in use of the module 900, these components are provided externally of the module 900.

The module 900 may combine different semiconductor materials and/or process node technologies. For example, the modulator IC package 100, 200, 300 of the module 900 may be implemented using silicon or silicon-based devices (fabricated, for example, using a CMOS- or BiCMOS-based process) while the switches of the half bridge(s) 410, 510, 520, 610 may be wide bandgap devices or high electron mobility transistor (HEMT) devices based on, for example, Gallium Nitride (GaN), Silicon Carbide (SIC), Gallium Oxide (Ga₂0₃) or other semiconductor materials.

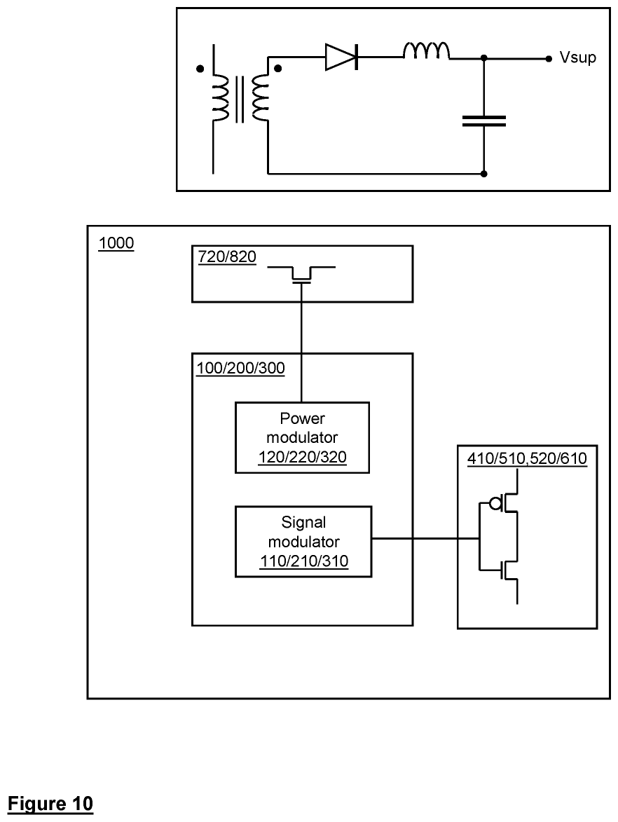

FIG. 10 is a schematic representation of a module comprising a modulator integrated circuit and switches of power converter circuitry.

The module, shown generally at 1000 in FIG. 10, includes a modulator IC package 100, 200, 300 of the kind described above that includes power modulator circuitry 120, 220, 320 and one or more instances of signal modulator circuitry 110, 210, 310.

The module 1000 further includes switches of power converter circuitry 140. For example, the module 1000 may include the power switch 720/820 of the power converter circuitry 700/800 described above with reference to FIGS. 7 and 8. However, the transformer, capacitor and inductor (if applicable) of the power converter circuitry 700, 800 of FIGS. 7 and 8 are not included in the module 1000. (Although FIG. 10 shows such external components arranged in a forward converter architecture of the kind described above with reference to FIG. 8, it will be appreciated that the external components could be arranged in a flyback converter architecture of the kind described above with reference to FIG. 7, or indeed some other power converter architecture.) Instead, in use of the module 1000, these components are provided externally of the module 1000. The diodes 730, 830 of the power converter circuitry 700, 800 may be provided as part of the module 1000, or alternatively may, in use of the module 1000, be provided externally of the module 1000.

Again, the module 1000 may combine different semiconductor materials and/or process node technologies. For example, the modulator IC package 100, 200, 300 of the module 1000 may be implemented using silicon or silicon-based devices (fabricated, for example, using a CMOS- or BiCMOS-based process), while the power switches 720, 820 of the power converter circuitry 700, 800 may be high electron mobility transistor (HEMT) devices based on, for example, Gallium Nitride (GaN), Silicon Carbide (SIC), Gallium Oxide (Ga₂0₃) or other semiconductor materials.

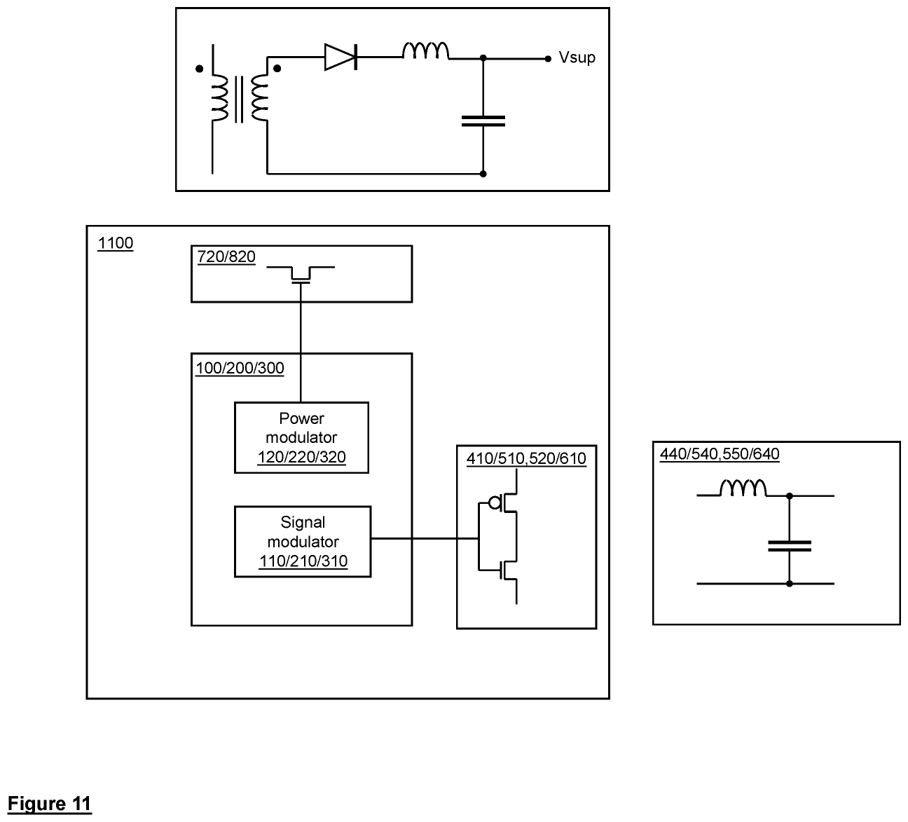

FIG. 11 is a schematic representation of a module comprising a modulator integrated circuit, switches of output stage circuitry, and switches of power converter circuitry.

The module, shown generally at 1100 in FIG. 11, includes a modulator IC package 100, 200, 300 of the kind described above that includes power modulator circuitry 120, 220, 320 and one or more instances of signal modulator circuitry 110, 210, 310.

The module 1100 further includes switches of output stage circuitry 130. For example, the module 1100 may include the half-bridges 410, 510, 520, 610 of the output stage circuitry 400, 500, 600 described above with reference to FIGS. 4-6. However, the inductors and capacitors of the output filter circuitry 440, 540, 550, 640 of the output stage circuitry 400, 500, 600 of FIGS. 4-6 are not included in the module 900. Instead, in use of the module 1100, these components are provided externally of the module 1100.

The module 1100 further includes switches of power converter circuitry 140. For example, the module 1100 may include the power switch 720/820 of the power converter circuitry 700/800 described above with reference to FIGS. 7 and 8. However, the transformer, capacitor and inductor (if applicable) of the power converter circuitry 700, 800 of FIGS. 7 and 8 are not included in the module 1100. (Again, although FIG. 11 shows such external components arranged in a forward converter architecture of the kind described above with reference to FIG. 8, it will be appreciated that the external components could be arranged in a flyback converter architecture of the kind described above with reference to FIG. 7, or indeed some other power converter architecture.) Instead, in use of the module 1100, these components are provided externally of the module 1100. The diodes 730, 830 of the power converter circuitry 700, 800 may be provided as part of the module 1100, or alternatively may, in use of the module 1000, be provided externally of the module 1100.

Again, the module 1100 may combine different semiconductor materials and/or process node technologies. For example, the modulator IC package 100, 200, 300 of the module 1000 may be implemented using silicon or silicon-based devices (fabricated, for example, using a CMOS- or BiCMOS-based process), while the switches of the half bridge(s) 410, 510, 520, 610 and/or the power switches 720, 820 of the power converter circuitry 700, 800 may be high electron mobility transistor (HEMT) devices based on, for example, Gallium Nitride (GaN), Silicon Carbide (SIC), Gallium Oxide (Ga₂0₃) or other semiconductor materials.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A modulator integrated circuit (IC) package comprising:
signal modulator circuitry; and
power modulator circuitry,
wherein the signal modulator circuitry is configured to receive an input signal and to supply a modulated output signal to output stage circuitry external to the modulator IC package,
and wherein the power modulator circuitry is configured to control power converter circuitry, external to the modulator IC package, operative to provide a supply voltage to the output stage circuitry.

2. The modulator IC package of claim 1, wherein the signal modulator circuitry and the power modulator circuitry are integrated in a single integrated circuit die.

3. The modulator IC package of claim 1, wherein the signal modulator circuitry and the power modulator circuitry are configured to receive a common clock signal.

4. The modulator IC package of claim 1, wherein the power modulator circuitry is configured to control the power converter circuitry based on the supply voltage provided by the power converter circuitry to the output stage circuitry.

5. The modulator IC package of claim 1, further comprising first monitor circuitry for monitoring the supply voltage provided by the power converter circuitry to the output stage circuitry.

6. The modulator IC package of claim 5, wherein the power modulator circuitry is configured to control the power converter circuitry based at least in part on a first monitor output signal output by the first monitor circuitry.

7. The modulator IC package of claim 5, wherein the signal modulator circuitry is configured to control a parameter of the modulated output signal based at least in part on a first monitor output signal output by the first monitor circuitry.

8. The modulator IC package of claim 7, wherein the parameter comprises one or more of: a pulse width; a duty cycle; a peak signal amplitude; a gain applied to the modulated output signal; or a compression applied to the modulated output signal.

9. The modulator IC package of any of claim 5, wherein the first monitor circuitry comprises analog to digital converter (ADC) circuitry.

10. The modulator IC package of claim 5, wherein an output of the first monitor circuitry is coupled to an input of the signal modulator circuitry such that the signal monitor circuitry receives a first monitor output signal output by the first monitor circuitry.

11. The modulator IC package of claim 1, further comprising second monitor circuitry for monitoring an operational parameter of the output stage circuitry.

12. The modulator IC package of claim 11, wherein the signal modulator circuitry is configured to control a parameter of the modulated output signal based at least in part on a second monitor output signal output by the second monitor circuitry.

13. The modulator IC package of claim 12, wherein the parameter comprises one or more of: a pulse width; a duty cycle; a peak signal amplitude; a gain applied to the modulated output signal; or a compression applied to the modulated output signal.

14. The modulator IC package of any of claim 1, wherein the signal modulator circuitry and the power modulator circuitry are configured to communicate with each other.

15. The modulator IC package of claim 1, wherein the power modulator circuitry is configured to receive a signal indicative of the input signal and to control the power converter circuitry based at least in part on the signal indicative of the input signal.

16. The modulator IC package of claim 15, wherein the power modulator circuitry is operative to control the power converter circuitry to modulate the supply voltage based on the signal indicative of the input signal.

17. The modulator IC package of claim 16, wherein the power modulator circuitry is operative to control the power converter circuitry to modulate the supply voltage between a plurality of different supply voltage levels based on the signal indicative of the input signal.

18. The modulator IC package of claim 16, wherein the power modulator circuitry is operative to control the power converter circuitry to maintain a fixed voltage difference between the supply voltage and a voltage of the input signal or between the supply voltage and an output voltage of the output stage circuitry.

19. The modulator IC package of claim 1, wherein the modulator IC package comprises a plurality of instances of signal modulator circuitry, wherein each instance of signal modulator circuitry is configured to receive an input signal and to supply a respective modulated output signal to a respective instance of output stage circuitry external to the modulator IC package.

20. The modulator IC package of claim 1, wherein the signal modulator circuitry comprises class D modulator circuitry.

21. The modulator IC package of claim 1, wherein the signal modulator circuitry and/or the power modulator circuitry is implemented in digital circuitry.

22. The modulator IC package of claim 1, wherein the modulated output signal is for controlling output stage circuitry for driving one or more of:
an audio transducer;
a haptic transducer;
a motor; and
a lighting transducer.

23. A module comprising:
the modulator integrated circuit package of claim 1; and
switches of power converter circuitry; and/or
switches of output stage circuitry,
wherein the power modulator circuitry of the modulator integrated circuit package is operable to control the switches of the power converter circuitry; and/or
wherein the signal modulator circuitry of the modulator integrated circuit package is operable to control the switches of the output stage circuitry.

24. The module of claim 23, further comprising output filter circuitry for coupling to the output stage circuitry.

25. The module of claim 24, wherein the output filter circuitry comprises one or more of an inductor and a capacitor.

26. The module of claim 23, wherein the modulator integrated circuit package is implemented using devices based on a first semiconductor material or process and the switches of the power converter circuitry and/or the switches of the output stage circuitry are implemented using devices based on a second semiconductor material or process that is different from the first semiconductor material or process.

27. The module of claim 23, wherein the modulator integrated circuit package is implemented using silicon-based devices and the switches of the power converter circuitry are implemented using wide bandgap or high electron mobility devices.

28. A host device comprising a modulator integrated circuit package according to claim 1.

29. A host device according to claim 28, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device; a vehicle audio system; a lighting system; a haptic system; a motor control system; or a vehicle.
